(19) United States
(12) Patent Application Publication
(10) Pub. No.: US 2026/0045243 A1
(43) Pub. Date: Feb. 12, 2026

(54) Mouthpiece

(71) Applicant: YAMAHA CORPORATION, Hamamatsu-shi (JP)

(72) Inventors: Risa FUKUDA, Hamamatsu-shi (JP); Ichiro FUTOHASHI, Hamamatsu-shi (JP); Taku NAGAI, Hamamatsu-shi (JP); Kazuhiro FUJITA, Hamamatsu-shi (JP)

(21) Appl. No.: 18/747,876

(22) Filed: Jun. 19, 2024

Related U.S. Application Data
(63) Continuation of application No. PCT/JP2022/040703, filed on Oct. 31, 2022.

(30) Foreign Application Priority Data
Dec. 22, 2021 (JP) 2021-208222

(51) Int. Cl. G10H 3/14; G10D 7/08; H10N 30/85; H10N 30/87; H10N 30/88

(52) U.S. Cl. CPC G10H 3/143; G10D 7/08; H10N 30/85; H10N 30/871; H10N 30/872; H10N 30/883; G10H 2220/535; G10H 2230/221

(57) ABSTRACT

A mouthpiece includes a body, a piezoelectric sensor, and a support structure. The body defines a conduit for air. The piezoelectric sensor includes a piezoelectric element having a porous layer compressable and deformable by vibration of the air. The piezoelectric sensor is configured to generate a detection signal based on compression and deformation of the porous layer. The support structure supports the piezoelectric element in the conduit.

### CROSS-REFERENCE TO RELATED APPLICATIONS

The present application is a continuation application of International Application No. PCT/JP2022/040703, filed Oct. 31, 2022, which claims priority to Japanese Patent Application No. 2021-208222, filed Dec. 22, 2021. The contents of these applications are incorporated herein by reference in their entirety.

### BACKGROUND

The present invention relates to a mouthpiece of a wind instrument.

Generally, a microphone is positioned adjacent to the wind instrument to convert its sound into an electrical signal. The microphone obtains vibrating air propagating away from the wind instrument as the sound of the wind instrument. Another technique is to obtain air vibrations generated in a wind instrument as its sound. For example, U.S. Pat. No. 3,543,629B1 discloses a piezoelectric element made of ceramics and embedded in a mouthpiece of a wind instrument. The piezoelectric element converts air vibrations in the mouthpiece into an electrical signal.

Piezoelectric elements made of ceramics are subject to various constraints regarding their installation positions. For example, due to susceptibility of ceramics to cracking, a ceramic piezoelectric element requires attachment to a tube surface of a wind instrument. In this case, a material such as epoxy resin must be placed between the tube surface and the piezoelectric element to prevent the vibration of the tube wall from being transmitted to the piezoelectric element. Due to these requirements, the positioning of piezoelectric elements was highly restricted. Furthermore, these requirements sometimes made it challenging to align the sound of the wind instrument with the sound represented by the electrical signal. Under the circumstances, it is preferable to achieve a flat frequency response when converting air vibrations into electrical signals.

An object of the present disclosure is to convert air vibrations in a mouthpiece into electrical signals while maintaining as flat a frequency response as possible.

### SUMMARY

One aspect is a mouthpiece that includes a body, a piezoelectric sensor, and a support structure. The body defines a conduit for air. The piezoelectric sensor includes a piezoelectric element having a porous layer compressable and deformable by vibration of the air. The piezoelectric sensor is configured to generate a detection signal based on compression and deformation of the porous layer. The support structure supports the piezoelectric element in the conduit.

A more complete appreciation of the present disclosure and many of the attendant advantages thereof will be readily obtained as the same becomes better understood by reference to the following detailed description when considered in connection with the following figures, in which:

### BRIEF DESCRIPTION OF THE DRAWINGS

FIG. 1 is a schematic illustration of a mouthpiece according to an embodiment;

FIG. 2 is a schematic illustration of a cross-section structure of the mouthpiece according to the embodiment;

FIG. 3 is a schematic illustration of a cross-section structure (cut along a plane indicated by the line A1-A2 illustrated in FIG. 1) of a piezoelectric module according to the embodiment;

FIG. 4 is a development drawing of the piezoelectric module according to the embodiment;

FIG. 5 is a schematic illustration of a partially enlarged cross-section structure (cut along a plane indicated by the line B1-B2 illustrated in FIG. 4) of the piezoelectric module according to the embodiment;

FIG. 6 is a schematic illustration of a circuit configuration of a piezoelectric sensor according to the embodiment;

FIG. 7 is an enlarged illustration of a part (region SA illustrated in FIG. 2) of a cross-section structure of the mouthpiece according to the embodiment;

FIG. 8 is a schematic illustration of a cross-section structure of the mouthpiece according to an embodiment;

FIG. 9 is a schematic illustration of a cross-section structure of a piezoelectric module according to the embodiment;

FIG. 10 is a schematic illustration of a cross-section structure of a mouthpiece according to an embodiment;

FIG. 11 is a schematic illustration of a cross-section structure of a piezoelectric module according to the embodiment;

FIG. 12 is a schematic illustration of a cross-section structure of a mouthpiece according to an embodiment;

FIG. 13 is a schematic illustration of a circuit configuration of a piezoelectric sensor according to the embodiment;

FIG. 14 is a schematic illustration of a cross-section structure of a piezoelectric module according to an embodiment;

FIG. 15 is a schematic illustration of a partially enlarged cross-section structure of a piezoelectric module according to the embodiment;

FIG. 16 is a schematic illustration of a cross-section structure of a piezoelectric module according to an embodiment;

FIG. 17 is a schematic illustration of a cross-section structure of a mouthpiece according to an embodiment; and

FIG. 18 is a schematic illustration of a cross-section structure of a piezoelectric module according to the embodiment.

### DESCRIPTION OF THE EMBODIMENTS

The present specification is applicable to a mouthpiece.

Embodiments of the present disclosure will be described in detail by referring to the accompanying drawings. The embodiments presented below serve as illustrative examples of the present disclosure and are not intended to limit the scope of the present disclosure. In the accompanying drawings referenced in the embodiments, similar reference numerals, characters, or symbols may be used to indicate corresponding or identical elements. For example, to distinguish like elements, “A” may be appended to a reference numeral and “B” may be appended to the same reference numeral. The accompanying drawings are schematic and intended for descriptive purposes only. For example, the dimension ratios depicted may not accurately reflect the actual dimensions. Additionally, certain configuration details may be omitted from the illustrations.

A mouthpiece according to an embodiment for a wind instrument has a function of converting sound of the wind instrument into an electrical signal. This function is implemented by a piezoelectric element that generates a voltage based on compression of a porous layer. A configuration of such mouthpiece will be described below.

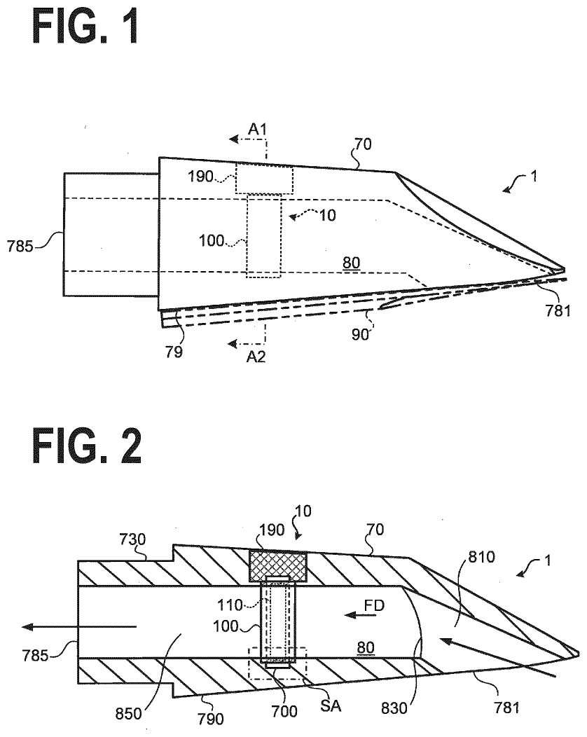

FIG. 1 is a schematic illustration of a mouthpiece according to an embodiment. FIG. 2 is a schematic illustration of a cross-section structure of the mouthpiece according to the embodiment. In the example illustrated in FIG. 1, a mouthpiece 1 is a mouthpiece used for a saxophone. The cross-section illustrated in FIG. 2 is perpendicular to a surface of a table 790 of the mouthpiece 1. The table 790 is a part to which a reed 90 of the saxophone is connected. The cross-section illustrated in FIG. 2 is also a surface passing through the center of the mouthpiece 1. The mouthpiece 1 includes a body 70 and a piezoelectric sensor 10. The body 70 includes an intake port 781 and an exhaust port 785. The intake port 781 is referred to as a window. The exhaust port 785 is formed at a shank 730. The body 70 defines a conduit for air. Specifically, the inner surface of the body 70 defines a conduit 80 for air. The conduit 80 includes a chamber 810, a throat 830, and a bore 850. When a user blows air into the conduit 80 through the intake port 781, the air passes through the chamber 810, the throat 830, and the bore 850 and flows out of the conduit 80 through the exhaust port 785.

The piezoelectric sensor 10 includes a piezoelectric module 100 and an output module 190. The piezoelectric module 100 includes a piezoelectric element 110. The piezoelectric element 110 generates an electrical signal based on the pressure applied to the piezoelectric element 110. The piezoelectric module 100 is supported by a support structure 700. The support structure 700 is formed at the inner surface of the body 70. The support structure 700 can be regarded as a structure for supporting the piezoelectric element 110 in the conduit 80. In this example, the piezoelectric element 110 is provided further in a flowing direction in which the air flows than the throat 830 of the conduit 80. That is, the piezoelectric element 110 is provided at the bore 850.

The output module 190 is electrically connected to the piezoelectric module 100 to amplify and output the electrical signal generated at the piezoelectric module 100. The output module 190 may include, as a power source, a secondary battery or a replaceable primary battery. Alternatively, the output module 190 may include a terminal to receive external power supply. The elements of the mouthpiece 1 will be described in more detail below.

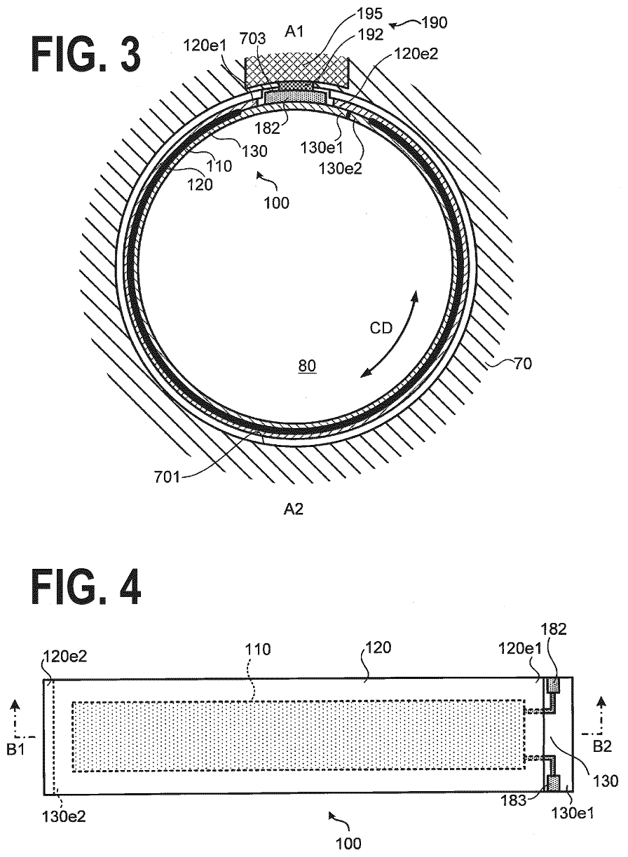

FIG. 3 is a schematic illustration of a cross-section structure (cut along a plane indicated by the line A1-A2 illustrated in FIG. 1) of the piezoelectric module 100 according to the embodiment. As illustrated in FIG. 3, the piezoelectric module 100 is a sheet-shaped member bent along the inner surface of the body 70. The piezoelectric module 100 includes a protection film 120 and a protection film 130. An example of the protection film 120 and the protection film 130 is an insulation resin film. Such protection films 120 and 130 are provided holding the piezoelectric element 110 between the protection films 120 and 130.

The protection film 120 and the protection film 130 physically protect the piezoelectric element 110 and prevent a leakage of water to the piezoelectric element 110. An end 120e2 of the protection film 120 and an end 130e1 of the protection film 130 are connected to each other. Due to this connection, the piezoelectric module 100 is in the shape of the circumferential surface of an approximately circular cylinder. That is, the piezoelectric module 100 has a cylindrical shape. A configuration of the piezoelectric module 100 will be further described below by referring to FIGS. 3, 4, and 5.

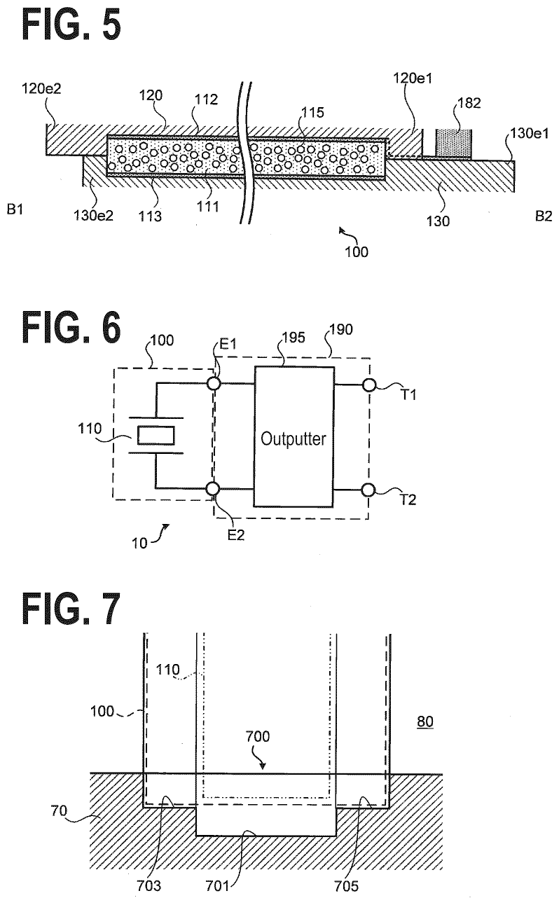

FIG. 4 is a development drawing of the piezoelectric module 100 according to the embodiment. FIG. 5 is a schematic illustration of a partially enlarged cross-section structure (cut along a plane indicated by the line B1-B2 illustrated in FIG. 4) of the piezoelectric module 100 according to the embodiment. The development drawing illustrated in FIG. 4 is an imaginary drawing showing the piezoelectric module 100 developed on a plane, with the end 120e2 of the protection film 120 and the end 130e1 of the protection film 130 disconnected from each other. In a view of the piezoelectric element 110 from a direction perpendicular to the plane of FIG. 4, the piezoelectric element 110 has a longitudinal length in a particular direction. More specifically, the piezoelectric element 110 has an approximately rectangular shape. The longitudinal length of the piezoelectric element 110 corresponds to the longitudinal side of this approximately rectangular shape. The piezoelectric element 110 may have any other shape, such as an elliptic shape, insofar as the piezoelectric element 110 has a longitudinal length in a particular direction. In a case of an elliptic shape, the longitudinal length corresponds to a direction along the longitudinal axis of the elliptic shape. The piezoelectric element 110 may even have a shape without a longitudinal length in a particular direction. Examples of such shape includes a square shape and a circular shape. The cross-section illustrated in FIG. 5 corresponds to a surface cut along the longitudinal length of the piezoelectric element 110.

The piezoelectric element 110 is sealed by the protection film 120 and the protection film 130. In this configuration, there is an area around the piezoelectric element 110 where the protection film 120 and the protection film 130 directly contact each other, that is, an area where the piezoelectric element 110 does not exist. In the following description, the area of the piezoelectric module 100 where the piezoelectric element 110 does not exist may occasionally be referred to as non-detection area. Also in the following description, the area of the piezoelectric module 100 where the piezoelectric element 110 exists may occasionally be referred to as detection area.

The piezoelectric element 110 includes a porous layer 111, an electrode 112, and an electrode 113. The electrode 112 and the electrode 113 hold the porous layer 111 between the electrode 112 and the electrode 113. The porous layer 111 is an electret layer with a multiplicity of micropores 115 formed in an insulation resin such as polypropylene. The porous layer 111 has electric charge inside the porous layer 111. The electric charge is provided in the porous layer 111 in advance by, for example, corona discharge. The micropores 115 are polarized by the voltage applied to the electrode 112 and the electrode 113 and the electric charge provided in the porous layer 111.

A possible material of the porous layer 111 is an electret material disclosed in WO/2018/101359. The electrode 112 and the electrode 113 each may be an electrode layer disclosed in WO/2018/101359. The ratio of the micropores 115 in the porous layer 111 is preferably 20% and more and 80% or less. This ratio corresponds to the empty hole ratio disclosed in WO/2018/101359. The lower limit of the density of the porous layer 111 is preferably 0.2 g/cm³, more preferably 0.4 g/cm³. The upper limit of the density of the porous layer 111 is preferably 0.8 g/cm³, more preferably 0.6 g/cm³. The lower limit of the elasticity ratio of the porous layer 111 in its thickness direction is preferably 0.1 MPa, more preferably 0.3 MPa. The upper limit of the elasticity ratio of the porous layer 111 in its thickness direction is preferably 10 MPa, more preferably 2 MPa. These elasticity ratios are values measured in accordance with JIS-K7161 (2014).

When the porous layer 111 is compressed in its thickness direction, the micropores 115 is deformed, causing a change in the level of polarization of the micropores 115, leading to a change in the potential difference between the electrode 112 and the electrode 113. Thus, the piezoelectric element 110 generates an electrical signal based on the compression and deformation of the porous layer 111. In this example, the piezoelectric element 110 and the porous layer 111 can be substantially identical in shape in a side view of the piezoelectric module 100. The piezoelectric element 110 can be regarded as an area where the porous layer 111, the electrode 112, and the electrode 113 are superimposed on each other.

In this example, the piezoelectric module 100 includes a connection electrode 182 and a connection electrode 183. The connection electrode 182 and the connection electrode 183 are provided on the protection film 130. The electrode 112 is connected to the connection electrode 182. The electrode 113 is connected to the connection electrode 183. With this configuration, the electrical signal based on the compression and deformation of the porous layer 111 is output as the potential difference between the connection electrode 182 and the connection electrode 183. The electrode 112 and the connection electrode 182 may be integrally formed. The electrode 113 and the connection electrode 183 may be integrally formed. The protection film 120 has an end 120e1 and the end 120e2. The end 120e1 and the end 120e2 are two ends of the longitudinal length of the protection film 120. The protection film 130 has the end 130e1 and an end 130e2. The end 130e1 and the end 130e2 are two ends of the longitudinal length of the protection film 130. In this example, the connection electrodes 182 and 183 are provided between the end 120e1 and the end 130e1.

The piezoelectric module 100 is a flexible bendable sheet. This configuration of the piezoelectric module 100 being a sheet increases the degree of freedom of installing the piezoelectric module 100 in the conduit 80. By bending the piezoelectric module 100 with the protection film 120 on the outside and the protection film 130 on the inside, the longitudinal length of the piezoelectric element 110 is bent in a circumferential direction CD of the inner surface of the body 70, as illustrated in FIG. 3. The short length of the piezoelectric element 110 extends in the flowing direction of air in the conduit 80. As illustrated in FIG. 3, the end 120e2 and the end 130e1 may contact each other. Specifically, the positions of the end 120e2 and the end 130e1 may be fixed relative to each other using an agent such as a binder.

Both the connection electrodes 182 and 183 are provided between the end 120e1 and the end 120e2 on the protection film 130. As illustrated in FIG. 2, the piezoelectric module 100 is supported on the body 70 by the support structure 700. In this state, the connection electrode 182 is connected to a connection electrode 192 of the output module 190, as illustrated in FIG. 3. Similarly, the connection electrode 183 is connected to a connection electrode different from the connection electrode 192 (this connection of the connection electrode 183 can not be seen in FIG. 3). Via these connection electrodes, the electrical signal generated by the piezoelectric module 100 is supplied to an outputter 195 of the output module 190. The outputter 195 includes a preamplifier and a terminal. The preamplifier amplifies an electrical signal. The terminal outputs the amplified electrical signal as a detection signal. The outputter 195 may not necessarily include a preamplifier. Instead, the outputter 195 may include a filter, such as a high path filter, that permits a signal of a predetermined frequency band to pass through the filter.

FIG. 6 is a schematic illustration of a circuit configuration of the piezoelectric sensor 10 according to the embodiment. The electrical signal generated at the piezoelectric module 100 is supplied to the outputter 195 via input terminals E1 and E2. The outputter 195 amplifies the supplied electrical signal to obtain a detection signal, and supplies the detection signal to output terminals T1 and T2. This detection signal is a signal based on the compression and deformation of the porous layer 111. The output terminals T1 and T2 each may be provided in the form of a phone jack (plug). An external device obtains the detection signal from the output terminals T1 and T2. The detection signal may also be provided to the external device using other than the output terminals T1 and T2. Examples other than the output terminals T1 and T2 include a flexible flat cable and a coaxial cable, which are different in form from the output terminals T1 and T2. The outputter 195 may wirelessly communicate with the external device to transmit the detection signal to the external device. The external device may be a sound output device that outputs the detection signal in the form of sound; a sound processing device that processes the detection signal; or a sound recording device that records the detection signal.

FIG. 7 is an enlarged illustration of a part (region SA illustrated in FIG. 2) of a cross-section structure of the mouthpiece 1 according to the embodiment. The support structure 700 includes a depression provided at the inner surface of the body 70, which defines the conduit 80. In this example, the depression includes a first depression region 701, a second depression region 703, and a third depression region 705. The first depression region 701 is provided between the second depression region 703 and the third depression region 705. The first depression region 701 is more deeply depressed than the second depression region 703 and the third depression region 705.

The second depression region 703 and the third depression region 705 contact the protection film 120 (see FIG. 3), which is provided on the outer surface of the piezoelectric module 100. Due to this contact, the support structure 700 supports the piezoelectric module 100 in the conduit 80. In this example, a part of the protection film 120 corresponding to the non-detection area of the piezoelectric module 100 (the area where the piezoelectric element 110 does not exist) contacts the support structure 700. In other words, a part of the protection film 120 corresponding to the detection area of the piezoelectric module 100 (the area where the piezoelectric element 110 exists) is kept away from the body 70 by the first depression region 701. The piezoelectric element 110, therefore, can be said to be supported by the support structure 700 in the conduit 80 via the protection films 120 and 130.

The piezoelectric module 100 is fitted with the depression of the support structure 700. In this state, it is preferable that no part of the piezoelectric module 100 protrudes into the conduit 80 from the body 70. That is, the depth of the second depression region 703 and the depth of the third depression region 705 each may be greater than a total of the thickness of the protection film 120, the thickness of the piezoelectric element 110, and the thickness of the protection film 130. The difference between this total and the depth of the second depression region 703 or the third depression region 705 is preferably small.

This configuration minimizes the influence that the piezoelectric module 100 has on the shape of the conduit 80. Since the influence of the piezoelectric module 100 is minimized, the sound quality of the wind instrument is prevented from varying depending on a case that the piezoelectric module 100 is provided and a case that the piezoelectric module 100 is not provided. The support structure 700 may include a support member positioned on the conduit 80 side relative to the piezoelectric module 100 when the support member contacts the piezoelectric module 100. Specifically, an end of the piezoelectric module 100 is held between the support member and at least one of the second depression region 703 and the third depression region 705.

The detection area of the piezoelectric module 100 is kept away from the body 70 by the first depression region 701. With this configuration, the piezoelectric element 110 is separated from the body 70 by air. More specifically, a first surface of the porous layer 111 and a second surface opposite to the first surface are separated from the body 70 by air. The first surface corresponds to the electrode 112 side surface of the porous layer 111, and the second surface corresponds to the electrode 113 side surface of the porous layer 111. Therefore, the first surface of the porous layer 111 corresponds to the body 70 side surface.

Thus, the detection area is separated from the body 70 by air, instead of directly contacting the body 70. This configuration ensures that the vibration transmitted to the mouthpiece 1 is less likely to be transmitted to the porous layer 111. The vibration transmitted to the mouthpiece 1 is a vibration other than the air vibration component in the conduit 80. An example of such vibration is a vibration caused by operating the keys of the wind instrument to which the mouthpiece 1 is connected. By ensuring that the vibration transmitted to the mouthpiece 1 is less likely to be transmitted to the porous layer 111, the influence that such vibration has on the compression and deformation of the porous layer 111 is minimized. The vibration transmitted to the mouthpiece 1 is a component different from the sound of a wind instrument. In light of this fact, such vibration is preferably not included in the detection signal.

By playing a wind instrument using the mouthpiece 1 connected to the wind instrument, air vibration occurs in the wind instrument. This air vibration also occurs in the conduit 80 of the mouthpiece 1. The air vibration occurring in the conduit 80 causes the porous layer 111, which is provided at the conduit 80, to be compressed and deformed. The sound impedance of the porous layer 111 is close to the sound impedance of air due to the existence of the large number of micropores 115.

With this configuration, the electrical signal obtained by the compression and deformation of the porous layer 111 is a signal obtained by converting the air vibration in the conduit 80 with as flat a frequency response as possible. Additionally, the piezoelectric module 100 is provided in a region of the conduit 80 where the air vibration's antinode exists. This configuration improves the accuracy of air vibration detection.

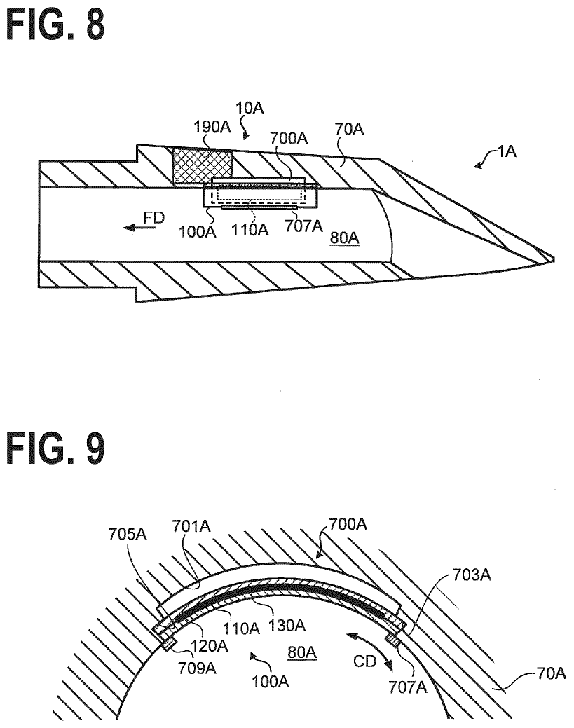

FIG. 8 is a schematic illustration of a cross-section structure of a mouthpiece 1A according to an embodiment. FIG. 9 is a schematic illustration of a cross-section structure of a piezoelectric element 110A according to this embodiment. FIG. 8 corresponds to FIG. 2. FIG. 9 corresponds to FIG. 3. In the mouthpiece 1 according to the previous embodiment, the longitudinal length of the piezoelectric element 110 extends in the circumferential direction CD of the inner surface of the body 70. In the mouthpiece 1A according to this embodiment, a piezoelectric module 100A is provided such that the longitudinal length of the piezoelectric element 110A extends in a flowing direction FD. The flowing direction FD is a direction in which air flows in a conduit 80A.

The mouthpiece 1A includes a piezoelectric sensor 10A and a body 70A. The inner surface of the body 70A defines the conduit 80A. The piezoelectric sensor 10A includes a piezoelectric module 100A and an output module 190A. The output module 190A has functions similar to the functions of the output module 190 according to the previous embodiment.

The piezoelectric module 100A is a sheet-shaped member bent along the inner surface of the body 70A. The piezoelectric module 100A includes the piezoelectric element 110A and protection films 120A and 130A. The protection film 120A and the protection film 130A are provided holding the piezoelectric element 110A between the protection films 120A and 130A. As described above, the longitudinal length of the piezoelectric element 110A extends in the flowing direction FD of air in the conduit 80A. The short length of the piezoelectric element 110A extends in the circumferential direction CD of the inner surface of the body 70A. Thus, the piezoelectric module 100A according to this embodiment is opposite to the piezoelectric module 100 according to the previous embodiment in terms of the relationship between the longitudinal length and the short length.

A support structure 700A includes a depression provided at the inner surface of the body 70A, which defines the conduit 80A. In this example, the depression includes a first depression region 701A, a second depression region 703A, a third depression region 705A, a first support member 707A, and a second support member 709A. The first depression region 701A is provided between the second depression region 703A and the third depression region 705A. The first support member 707A and the second support member 709A are provided on the conduit 80A side relative to the piezoelectric module 100A, and support the piezoelectric module 100A. The first support member 707A and the second depression region 703A hold one end of the piezoelectric module 100A between the first support member 707A and the second depression region 703A. The second support member 709A and the third depression region 705A hold another end of the piezoelectric module 100A between the second support member 709A and the third depression region 705A.

The first depression region 701A is more deeply depressed than the second depression region 703A and the third depression region 705A. The second depression region 703A and the third depression region 705A contact the protection film 120A, which is provided on the outer surface of the piezoelectric module 100A. Due to this contact, the support structure 700A supports the piezoelectric module 100A in the conduit 80A. In this example, a part of the protection film 120A corresponding to a non-detection area of the piezoelectric module 100A (the area where the piezoelectric element 110A does not exist) contacts the support structure 700A. With the piezoelectric module 100A supported by the support structure 700A, the piezoelectric module 100A and the output module 190A are electrically connected to each other.

The longitudinal length of the piezoelectric element 110A extends along the longitudinal length of the mouthpiece 1A, that is, extends in the flowing direction FD of air. This configuration ensures that when air vibration occurs in the conduit 80A of the mouthpiece 1A, the air vibration's antinode is more likely to come within a detection area of the piezoelectric module 100A where the piezoelectric element 110A exists. As a result, tolerance increases for the accuracy of the position at which the piezoelectric element 110A is installed.

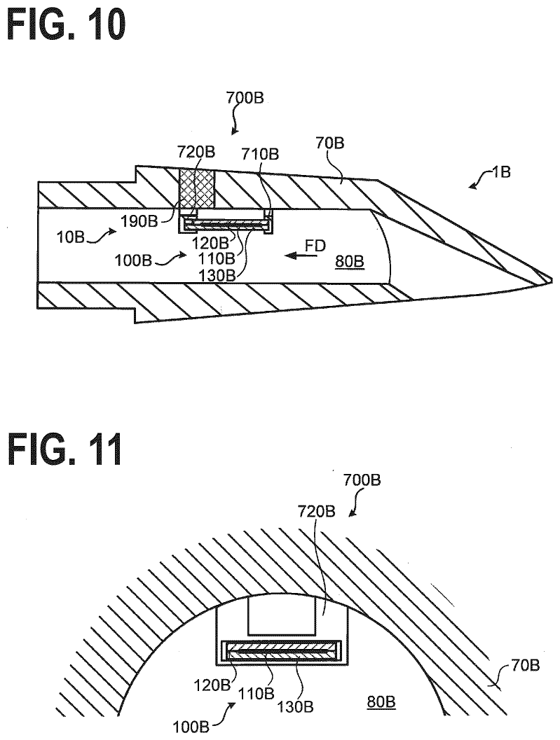

FIG. 10 is a schematic illustration of a cross-section structure of a mouthpiece 1B according to an embodiment. FIG. 11 is a schematic illustration of a cross-section structure of a piezoelectric module 100B according to this embodiment. FIG. 10 corresponds to FIG. 2. FIG. 11 corresponds to FIG. 3. The mouthpiece 1B according to this embodiment includes the piezoelectric module 100B. The piezoelectric module 100B is provided in a planar state, as opposed to the bent state employed in the mouthpiece 1 and the mouthpiece 1A according to the previous embodiments, that is, as opposed to the curved shapes of the piezoelectric modules 100 and 100A.

The mouthpiece 1B includes a piezoelectric sensor 10B and a body 70B. The inner surface of the body 70B defines a conduit 80B. The piezoelectric sensor 10B includes the piezoelectric module 100B and an output module 190B. The output module 190B has functions similar to the functions of the output module 190 according to the previous embodiment.

The piezoelectric module 100B includes a piezoelectric element 110B and protection films 120B and 130B, similarly to the piezoelectric module 100. The protection film 120B and the protection film 130B are provided holding the piezoelectric element 110B between the protection films 120B and 130B. The longitudinal length of the piezoelectric element 110B extends in the flowing direction FD of air in the conduit 80B, and the short length of the piezoelectric element 110B is not bent. As a whole, the piezoelectric element 110B has a planar shape. Thus, the piezoelectric module 100B is a sheet-shaped member provided in a planar state, as described above.

The support structure 700B includes a first protrusion 710B and a second protrusion 720B. The first protrusion 710B and the second protrusion 720B protrude into the conduit 80B from the body 70B. The second protrusion 720B is provided further in the flowing direction FD than the first protrusion 710B. The first protrusion 710B supports the piezoelectric module 100B by holding one longitudinal end of the piezoelectric module 100B. The second protrusion 720B supports the piezoelectric module 100B by holding another longitudinal end of the piezoelectric module 100B. The parts of the piezoelectric module 100B supported by the support structure 700B correspond to a non-detection area of the piezoelectric module 100B (where the piezoelectric element 110B does not exist)

With the piezoelectric module 100B supported by the support structure 700B, a connection electrode of the piezoelectric module 100B and a connection electrode of the output module 190B contact each other, causing the piezoelectric module 100B and the output module 190B to be electrically connected to each other. The support structure 700B may support two short length ends of the piezoelectric module 100B. The longitudinal length and the short length of the piezoelectric module 100B may be interchanged, in which case the piezoelectric module 100B has a short length in the flowing direction FD.

By using the piezoelectric module 100B, which is provided in a planar state, the piezoelectric module 100B becomes easier to support in the mouthpiece 1B. Additionally, the piezoelectric module 100B is kept away from the inner surface of the body 70B by the support structure 700B. This configuration reduces the possibility of a vibration component other than air vibration being included in the detection signal.

The configuration of the support structure 700B may be applied to the mouthpiece 1 according to a previous embodiment to keep the piezoelectric module 100 away from the inner surface of the body 70. The configuration of the support structure 700B may be applied to the mouthpiece 1A according to a previous embodiment to keep the piezoelectric module 100A away from the inner surface of the body 70A.

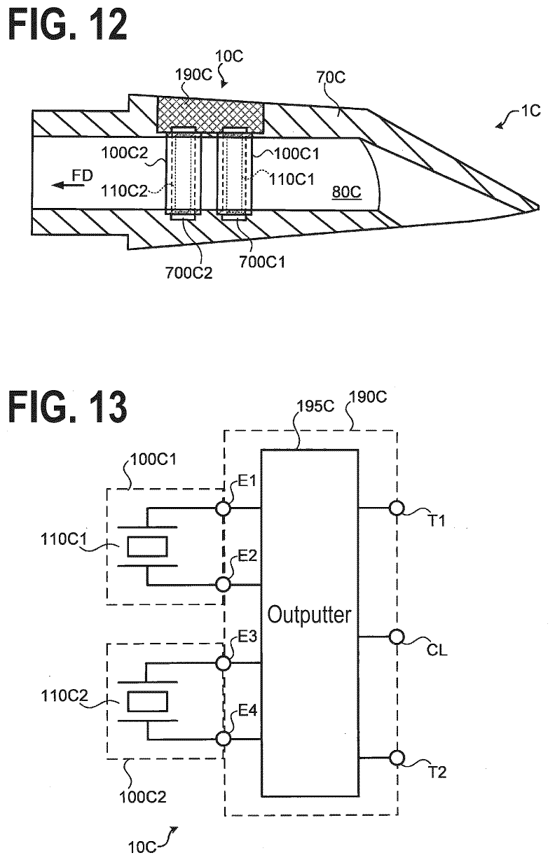

FIG. 12 is a schematic illustration of a cross-section structure of a mouthpiece 1C according to an embodiment. FIG. 12 corresponds to FIG. 2. The mouthpiece 1C according to this embodiment includes a piezoelectric sensor 10C and a body 70C. The inner surface of the body 70C defines a conduit 80C. The piezoelectric sensor 10C includes a piezoelectric module 100C1, a piezoelectric module 100C2, and an output module 190C. While in this example the piezoelectric sensor 10C uses two piezoelectric modules 100C1 and 100C2, the piezoelectric sensor 10C may use a larger number of piezoelectric modules.

The piezoelectric module 100C2 is provided further in the flowing direction FD of air in the conduit 80C than the piezoelectric module 100C1. The piezoelectric modules 100C1 and 100C2 each have a configuration similar to the configuration of the piezoelectric module 100 according to a previous embodiment. The piezoelectric module 100C1 includes a piezoelectric element 110C1. The piezoelectric element 110C1 is supported by a support structure 700C1. The piezoelectric module 100C2 includes a piezoelectric element 110C2. The piezoelectric element 110C2 is supported by a support structure 700C2. The support structures 700C1 and 700C2 each have a configuration similar to the configuration of the support structure 700 according to a previous embodiment.

The piezoelectric module 100C1 and the piezoelectric module 100C2 are electrically connected to the output module 190C. There are a plurality of possible examples for a circuit configuration of the piezoelectric sensor 10C, that is, a circuit configuration in which an electrical signal occurring in each of the piezoelectric module 100C1 and the piezoelectric module 100C2 is output as a detection signal. Three examples of such circuit configuration will be described below.

FIG. 13 is a schematic illustration of a circuit configuration of a piezoelectric sensor according to this embodiment. The output module 190C includes an outputter 195C. An electrical signal generated at the piezoelectric module 100C1 is supplied to the outputter 195C via the input terminals E1 and E2 (this electrical signal will be hereinafter occasionally referred to as electrical signal Sa1). An electrical signal generated at the piezoelectric module 100C2 is supplied to the outputter 195C via input terminals E3 and E4 (this electrical signal will be hereinafter occasionally referred to as electrical signal Sa2).

The outputter 195C uses the electrical signals Sa1 and Sa2 to supply detection signals to the output terminals T1 and T2. The outputter 195C receives a control signal via a control terminal CL. Upon receipt of the control signal, the outputter 195C controls a connection relationship between the input terminals E1 to E4 based on the control signal. The control signal is supplied from, for example, an external device or a switch provided at the mouthpiece 1C. By controlling this connection relationship, the detection signals supplied to the output terminals T1 and T2 are changed.

In this example, the outputter 195C is capable of switching between four detection modes (mode A to mode D) using a control signal. Mode A is a mode for widening a detection range. In mode A, the outputter 195C amplifies the potential between a node connecting E1 and E3 and a node connecting E2 and E4 to obtain a detection signal. By this connection method, the piezoelectric module 100C1 and the piezoelectric module 100C2 are connected in parallel to each other. That is, the output of the piezoelectric element 110C1 and the output of the piezoelectric element 110C2 are connected in parallel to each other.

Mode B is a mode for increasing the output level of the detection signal. In mode B, the outputter 195C connects E2 and E3 and amplifies the potential between E1 and E4 to obtain a detection signal. By this connection method, the piezoelectric module 100C1 and the piezoelectric module 100C2 are connected in series to each other. That is, the output of the piezoelectric element 110C1 and the output of the piezoelectric element 110C2 are connected in series to each other. In mode B, the output level of the detection signal is greater than in mode C and mode D, described later, resulting in an increase in detection sensitivity.

Mode C is a mode for using only the detection area of the piezoelectric module 100C1. In mode C, the outputter 195C does not use E3 and E4; instead, the outputter 195C obtains a detection signal based on the electrical signal Sa1, which is supplied from E1 and E2. That is, the detection signal in mode C is similar to the detection signal in a previous embodiment.

Mode D is a mode for using only the detection area of the piezoelectric module 100C2. In mode D, the outputter 195C does not use E1 and E2; instead, the outputter 195C obtains a detection signal based on the electrical signal Sa2, which is supplied from E3 and E4.

Thus, the detection signals in modes C and D are generated using the output from the piezoelectric element 110C1 or 110C2. When the piezoelectric element 110C1 and the piezoelectric element 110C2 are in a particular positional relationship, switching the detection mode to mode C or mode D may cause the relationship between the position of the air vibration's antinode and the detection area to differ. In light of this, it is possible to vary the tone of the detection signal.

Thus, the outputter 195C switches the detection mode between the four modes using a control signal. It is possible, however, for the outputter 195C to fix the detection mode to any one of the four modes. It is also possible for the outputter 195C to supply the detection signal to a larger number of output terminals to simultaneously output detection signals corresponding to a plurality of modes.

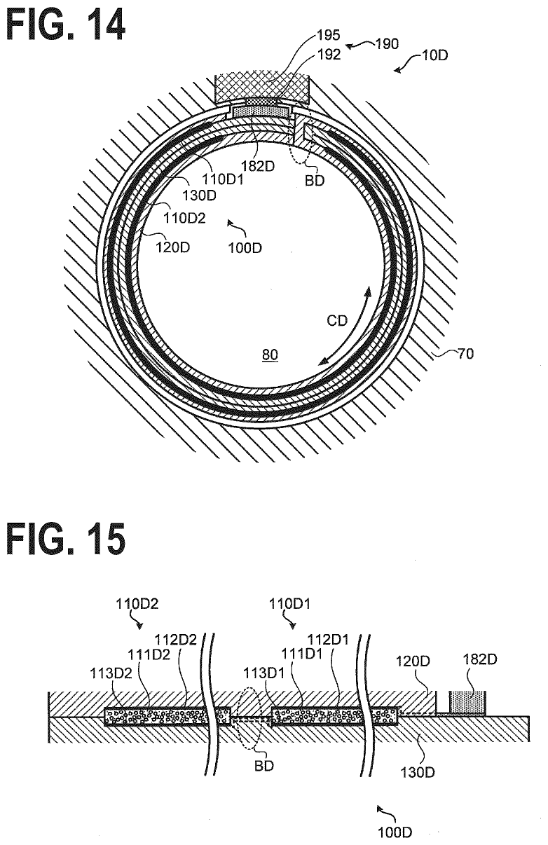

FIG. 14 is a schematic illustration of a cross-section structure of a piezoelectric module 100D according to an embodiment. FIG. 15 is a schematic illustration of a partially enlarged cross-section structure of the piezoelectric module 100D according to this embodiment. FIG. 14 corresponds to FIG. 3. FIG. 15 corresponds to FIG. 5. The piezoelectric module 100D according to this embodiment includes two piezoelectric elements 110D1 and 110D2.

The piezoelectric module 100D extends in the circumferential direction CD of the inner surface of the body 70. The piezoelectric module 100D is bent at a bending portion BD to make the two piezoelectric elements 110D1 and 110D2 overlap each other. With this configuration, the piezoelectric element 110D1 is provided at a position closer to the body 70 than the piezoelectric element 110D2 is to the body 70. While in this example the piezoelectric module 100D of the piezoelectric sensor 10D includes the two piezoelectric elements 110D1 and 110D2, the piezoelectric module 100D may include a larger number of piezoelectric elements.

The two piezoelectric elements 110D1 and 110D2 are sealed by a protection film 120D and a protection film 130D. Two detection areas corresponding to the two piezoelectric elements 110D1 and 110D2 are surrounded by non-detection areas. Between the piezoelectric element 110D1 and the piezoelectric element 110D2, there is a region where the protection film 120D and the protection film 130D contact each other. This region is the bending portion BD. The piezoelectric element 110D1 includes a porous layer 111D1, an electrode 112D1, and an electrode 113D1. The piezoelectric element 110D2 includes a porous layer 111D2, an electrode 112D2, and an electrode 113D2.

In this example, the electrode 113D1 and the electrode 113D2 are electrically connected to each other via a wire. The connection electrode 182D and the electrode 112D1 are connected to each other, and another connection electrode not illustrated and the electrode 112D2 are connected to each other. Thus, the piezoelectric element 110D1 and the piezoelectric element 110D2 are connected in series to each other between the two connection electrodes.

In the piezoelectric sensor 10D, a plurality of piezoelectric elements serving as detection areas overlap each other and are connected in series to each other. This configuration ensures that the output level of the detection signal increases as compared with the piezoelectric sensor 10 according to a previous embodiment. The increase in the output level of the detection signal leads to an increase in detection sensitivity.

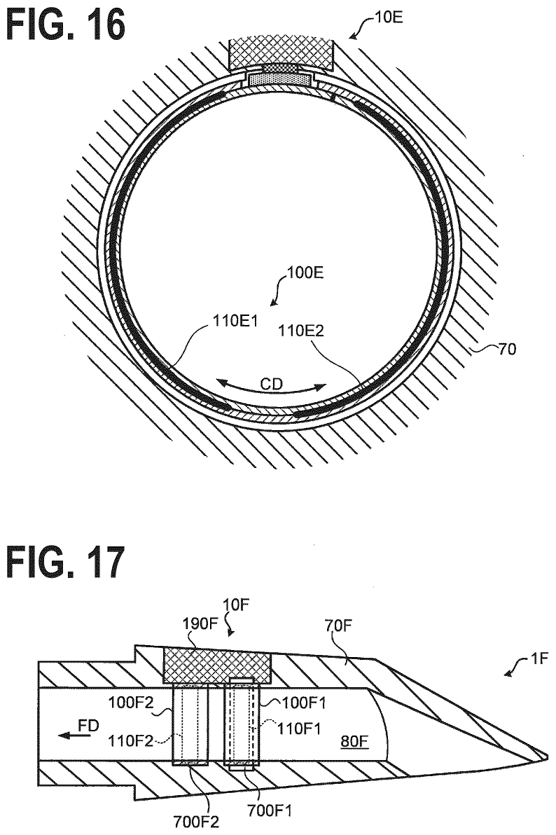

FIG. 16 is a schematic illustration of a cross-section structure of a piezoelectric module 100E according to an embodiment. FIG. 16 corresponds to FIG. 3. The piezoelectric module 100E according to this embodiment includes two piezoelectric elements 110E1 and 110E2.

The piezoelectric module 100E has a shape similar to the shape of the piezoelectric module 100D illustrated in FIG. 15. In the piezoelectric module 100E,however, no bending portion BD exists. The piezoelectric module 100E extends in the circumferential direction CD of the inner surface of the body 70. The piezoelectric element 110E1 extends in the circumferential direction CD relative to the piezoelectric element 110E2. While in this example the piezoelectric module 100E of the piezoelectric sensor 10E includes the two piezoelectric elements 110E1 and 110E2, which are connected in series to each other, the piezoelectric module 100E may include a larger number of piezoelectric elements.

In the piezoelectric sensor 10E, a plurality of piezoelectric elements serving as detection areas are connected in series to each other. This configuration ensures that the output level of the detection signal increases as compared with the piezoelectric sensor 10 according to a previous embodiment, even though the detection range becomes narrower. The increase in the output level of the detection signal leads to an increase in detection sensitivity.

FIG. 17 is a schematic illustration of a cross-section structure of a mouthpiece 1F according to an embodiment. FIG. 17 corresponds to FIG. 2. The mouthpiece 1F according to this embodiment includes a piezoelectric sensor 10F and a body 70F. The inner surface of the body 70F defines a conduit 80F. The piezoelectric sensor 10F includes a piezoelectric module 100F1, a piezoelectric module 100F2, and an output module 190F. While in this example the piezoelectric sensor 10F uses the two piezoelectric modules 100F1 and 100F2, the piezoelectric sensor 10F may use a larger number of piezoelectric modules.

The piezoelectric module 100F2 is provided further in the flowing direction FD of air than the piezoelectric module 100F1 in the conduit 80C. This positional relationship between the piezoelectric module 100F1 and the piezoelectric module 100F2 may be opposite. The piezoelectric module 100F1 has a configuration similar to the configuration of the piezoelectric module 100 according to a previous embodiment. The piezoelectric module 100F1 includes a piezoelectric element 110F1 and is supported by a support structure 700F1. The support structure 700F1 has a configuration similar to the configuration of the support structure 700 according to a previous embodiment.

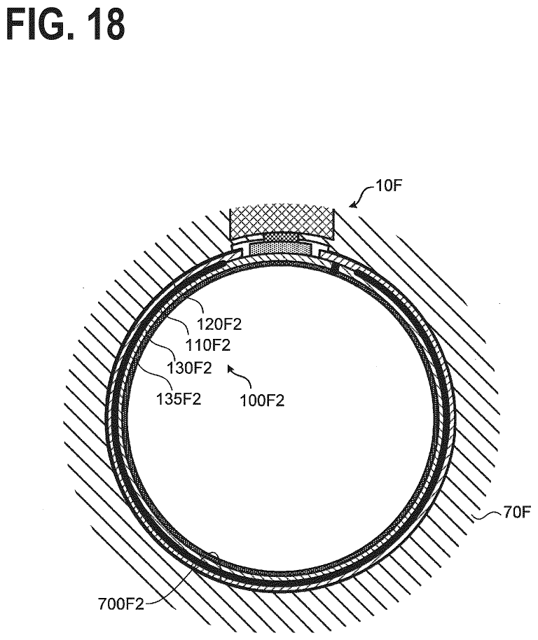

FIG. 18 is a schematic illustration of a cross-section structure of the piezoelectric module 100F1 according to this embodiment. FIG. 18 corresponds to FIG. 3 in terms of a piezoelectric module 100F2. A piezoelectric module 100F1 is approximately identical to the piezoelectric module 100 illustrated in FIG. 3. A piezoelectric element 110F2 of the piezoelectric module 100F2 is sealed by a protection film 120F2 and a protection film 130F2. The piezoelectric module 100F2 is supported by a support structure 700F2. The support structure 700F2 is provided at the inner surface of the body 70F. The support structure 700F2 has no structure corresponding to the first depression region 701. With this configuration, the protection film 120F2 contacts the body 70F even in the detection areas.

In this example, a weight layer 135F2 is provided further inward than the protection film 130F2, which is provided further inward than the protection film 120F2 in the conduit 80F. The weight layer 135F2 is preferably made of a material greater in specific gravity than the protection film 130F2. An example of such material is a copper foil. The weight layer 135F2, however, may not necessarily be a metal layer but may be an insulation layer.

The piezoelectric module 100F1 is identical to the piezoelectric module 100 according to a previous embodiment. Therefore, the piezoelectric module 100F1 is suitable for converting air vibration occurring in a wind instrument into a detection signal. In contrast, the piezoelectric module 100F2, which contacts the inner surface of the body 70F, is susceptible to vibration transmitted from the wind instrument to the mouthpiece 1F (this vibration may be hereinafter occasionally referred to as tube vibration component). Additionally, the vibration transmitted from the body 70F is emphasized by the weight layer 135F2 to contribute to the compression and deformation of the piezoelectric element 110F2. As a result, the electrical signal generated by the piezoelectric module 100F2 includes a high percentage of the tube vibration component.

The output module 190F receives an electrical signal generated by the piezoelectric module 100F1 (this electrical signal will be hereinafter occasionally referred to as electrical signal Sb1) and an electrical signal generated by the piezoelectric module 100F2 (this electrical signal will be hereinafter occasionally referred to as electrical signal Sb2). The output module 190F amplifies the electrical signal Sb1 and the electrical signal Sb2 to obtain two detection signals. Then, the output module 190F supplies detection signals to output terminals. In this case, the output module 190F may include output terminals through which to output the two detection signals. It is possible to use the output terminals T1 and T2, similarly to a previous embodiment. In this case, the output module 190F may perform signal processing of the two detection signals into a single detection signal. Alternatively, it is possible to use the circuit configuration according to a previous embodiment to output detection signals.

The electrical signal Sb1 and the electrical signal Sb2 differ in the ratio between the tube vibration component and the air vibration component. It is possible to use this ratio difference in the above-described signal processing. For example, the output module 190F may perform signal processing using the electrical signal Sb1 and the electrical signal Sb2 to generate a detection signal emphasizing the tube vibration component or generate a detection signal emphasizing the air vibration component.

### Modifications

The present disclosure will not be limited to the above-described embodiments and allows for various other modifications. For example, while the above-described embodiments have been described for clarity, not every configuration described is essential to the present disclosure. A configuration from one embodiment can be substituted with a configuration from another embodiment, or a configuration from one embodiment can be combined with a configuration from another embodiment. Each configuration described in the above embodiments can be partially or entirely subject to addition, deletion, or replacement with another configuration. Possible modifications will be described below. The following modifications are applicable to all the embodiments described above.

(1) The piezoelectric sensor 10 according to a previous embodiment is provided at a mouthpiece used for a saxophone. Another possible example is that the piezoelectric sensor 10 is provided at a mouthpiece used for a woodwind instrument, instead of a saxophone. For example, the piezoelectric sensor 10 may be provided at a mouthpiece of a woodwind instrument using a single reed or a double reed. In a case of a woodwind instrument using a double reed, the piezoelectric sensor 10 may be provided at a position corresponding to the mouthpiece. For example, the position corresponding to the mouthpiece is an oboe's tube and a bassoon's bocal. Another possible example is that the piezoelectric sensor 10 is provided at a mouthpiece of a woodwind instrument using no reed. In any mouthpiece, the piezoelectric sensor 10 may be provided at a position in the conduit such that the detection area(s) is adjacent to the air vibration's antinode. In a case of a mouthpiece of a flute, which is a woodwind instrument using no reed, the piezoelectric sensor 10 may be provided at the flute's headjoint.

The piezoelectric sensor 10 is also applicable to a mouthpiece of a brass instrument. In this case, the piezoelectric sensor 10 may be provided in a cup in the air conduit of a mouthpiece or at a position other than the cup. Examples of the position other than the cup is a throat and a position further downstream than the throat. An example of the position further downstream than the throat is a position corresponding to a back bore. At positions other than the cup, it is more difficult to detect lip vibrations.

(2) The support structure 700 may support the piezoelectric module 100 such that the piezoelectric module 100 is attachable and detachable to and from the mouthpiece 1. Alternatively, the support structure 700 may support the piezoelectric module 100 such that the piezoelectric module 100 is fixed to the mouthpiece 1. In a case that the piezoelectric module 100 is supported by the support structure 700 while being attachable and detachable to and from the mouthpiece 1, the piezoelectric module 100 can be replaced in a case of a failure. In a case that the piezoelectric module 100 is fixed to the mouthpiece 1, the piezoelectric module 100 and the output module 190 may be integrally formed.

In a case that the piezoelectric module according to any of the above-described embodiments has a cylindrical shape, as in a case of the piezoelectric module 100, the cylindrical shape may be deformed to be fitted into the mouthpiece 1 and brought back into the cylindrical shape to be supported by the support structure 700. In this case, the support structure 700 and the piezoelectric module 100 may be provided with a positioning structure for positioning of the connection electrodes. Additionally, at least a part of the output module 190 may be attachable and detachable to and from the mouthpiece 1. In this case, the piezoelectric sensor 10 as a whole may be removable from the mouthpiece 1.

(3) In the above-described embodiments, the inner surface of the mouthpiece 1 includes a curved surface, and the mouthpiece 1 has an approximately circular cross-section. Another possible example is that the inner surface of the mouthpiece 1 includes a combination of planar surfaces, and the mouthpiece 1 has an approximately rectangular cross-section. In a case that the inner surface of the mouthpiece 1 includes a combination of planar surfaces, the piezoelectric element is preferably provided to avoid spanning across two planes. That is, a single piezoelectric element is preferably provided at a single plane. In this case, the single piezoelectric element has a planar shape, instead of a bent shape.

(4) On the inside of the mouthpiece 1, the piezoelectric module 100 may be provided in a spiral form. In this case as well, the piezoelectric module 100 can be regarded as being bent along the inner surface of the body 70.

In the above-described embodiments, the piezoelectric element may have a shape with its longitudinal length oriented in a predetermined direction, and the longitudinal length of the piezoelectric element may be aligned with a flowing direction in which the air flows.

In the above-described embodiments, the piezoelectric element may have a first surface and a second surface opposite to the first surface. The first surface and the second surface are positioned facing the body with air interposed between the first surface and the body and between the second surface and the body.

In the above-described embodiments, the piezoelectric element may be bent along an inner surface of the body.

In the above-described embodiments, the piezoelectric element may have a shape with its longitudinal length oriented in a predetermined direction, and the longitudinal length of the piezoelectric element may be aligned with a circumferential direction of the inner surface of the body.

In the above-described embodiments, the support structure may have a depression provided at a surface of the body which surface defines the conduit The piezoelectric element may be provided at the depression.

In the above-described embodiments, the piezoelectric sensor may include a plurality of piezoelectric elements. The detection signal may be generated by connecting outputs of the plurality of piezoelectric elements in series.

In the above-described embodiments, the piezoelectric sensor may include a plurality of piezoelectric elements. The plurality of piezoelectric elements may at least include a first piezoelectric element and a second piezoelectric element. The first piezoelectric element may be aligned with a circumferential direction of an inner surface of the body relative to the second piezoelectric element.

In the above-described embodiments, the piezoelectric sensor may include a plurality of piezoelectric elements. The plurality of piezoelectric elements may at least include a first piezoelectric element and a second piezoelectric element. The first piezoelectric element may be provided at a position closer to the body than the second piezoelectric element.

In the above-described embodiments, the piezoelectric sensor may include a plurality of piezoelectric elements. The plurality of piezoelectric elements may at least include a first piezoelectric element and a second piezoelectric element. The second piezoelectric element may be provided further in a flowing direction in which the air flows than the first piezoelectric element.

In the above-described embodiments, the piezoelectric sensor may be configured to generate a second detection signal using an output of at least one of the plurality of piezoelectric elements.

While embodiments of the present disclosure have been described, the embodiments are intended as illustrative only and are not intended to limit the scope of the present disclosure. It will be understood that the present disclosure can be embodied in other forms without departing from the scope of the present disclosure, and that other omissions, substitutions, additions, and/or alterations can be made to the embodiments. Thus, these embodiments and modifications thereof are intended to be encompassed by the scope of the present disclosure. The scope of the present disclosure accordingly is to be defined as set forth in the appended claims.

What is claimed is:

1. A mouthpiece comprising:
a body defining a conduit for air;
a piezoelectric sensor including a piezoelectric element having a porous layer compressable and deformable by vibration of the air, the piezoelectric sensor being configured to generate a detection signal based on compression and deformation of the porous layer; and
a support structure supporting the piezoelectric element in the conduit.

2. The mouthpiece according to claim 1, wherein
the piezoelectric element has a shape with its longitudinal length oriented in a predetermined direction, and
the longitudinal length of the piezoelectric element is aligned with a flowing direction in which the air flows.

3. The mouthpiece according to claim 1, wherein the piezoelectric element has a first surface and a second surface opposite to the first surface, the first surface and the second surface being positioned facing the body with air interposed between the first surface and the body and between the second surface and the body.

4. The mouthpiece according to claim 1, wherein the piezoelectric element is bent along an inner surface of the body.

5. The mouthpiece according to claim 4, wherein
the piezoelectric element has a shape with its longitudinal length oriented in a predetermined direction, and
the longitudinal length of the piezoelectric element is aligned with a circumferential direction of the inner surface of the body.

6. The mouthpiece according to claim 1, wherein
the support structure includes a depression provided at a surface of the body which surface defines the conduit, and
the piezoelectric element is provided at the depression.

7. The mouthpiece according to claim 1, wherein
the piezoelectric sensor includes a plurality of piezoelectric elements, and
the detection signal is generated by connecting outputs of the plurality of piezoelectric elements in series.

8. The mouthpiece according to claim 1, wherein
the piezoelectric sensor includes a plurality of piezoelectric elements,
the plurality of piezoelectric elements at least include a first piezoelectric element and a second piezoelectric element, and
the first piezoelectric element extends in a circumferential direction of an inner surface of the body relative to the second piezoelectric element.

9. The mouthpiece according to claim 1, wherein
the piezoelectric sensor includes a plurality of piezoelectric elements,
the plurality of piezoelectric elements at least include a first piezoelectric element and a second piezoelectric element, and
the first piezoelectric element is provided at a position closer to the body than the second piezoelectric element.

10. The mouthpiece according to claim 1, wherein
the piezoelectric sensor includes a plurality of piezoelectric elements,
the plurality of piezoelectric elements at least include a first piezoelectric element and a second piezoelectric element, and
the second piezoelectric element is provided further in a flowing direction in which the air flows than the first piezoelectric element.

11. The mouthpiece according to claim 7, wherein the piezoelectric sensor is configured to generate a second detection signal using an output of at least one of the plurality of piezoelectric elements.
